(19) United States
(12) Patent Application Publication
(10) Pub. No.: US 2008/0237694 A1
(43) Pub. Date: Oct. 2, 2008

(54) Integrated circuit, cell, cell arrangement, method for manufacturing an integrated circuit, method for manufacturing a cell, memory module

(76) Inventors: Michael Specht, Muenchen (DE); Nicolas Nagel, Dresden (DE); Josef Willer, Riemerling (DE)

Correspondence Address: SLATER & MATSIL, L.L.P., 17950 PRESTON ROAD, SUITE 1000, DALLAS, TX, 75252, US

(21) Appl. No.: 11/728,960

(22) Filed: Mar. 27, 2007

(51) Int. Cl. H01L 29/792; H01L 21/336

(52) U.S. Cl. 257/324; 438/287; 257/E21.423; 257/E29.309

(57) ABSTRACT

The invention relates to integrated circuits, to a cell, to a cell arrangement, to a method for manufacturing an integrated circuit, to a method for manufacturing a cell, and to a memory module. In an embodiment of the invention, an integrated circuit is provided having a cell, the cell including a low-k dielectric layer, a first high-k dielectric layer disposed above the low-k dielectric layer, a charge trapping layer disposed above the first high-k dielectric layer, and a second high-k dielectric layer disposed above the charge trapping layer.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a cross sectional view of a conventional memory cell;

FIG. 2 shows a cross sectional view of another conventional memory cell;

FIG. 3 shows a cross sectional view of a dielectric layer stack of a cell in accordance with an embodiment of the invention;

FIG. 4 shows a cross sectional view of a cell in accordance with an embodiment of the invention;

FIG. 5 shows an energy band diagram of a memory cell in accordance with an embodiment of the invention;

FIG. 6 shows an energy band diagram of a portion of a memory cell in accordance with an embodiment of the invention in a programming mode;

FIG. 7 shows an energy band diagram of a portion of a memory cell in accordance with an embodiment of the invention in a non-programming mode;

FIG. 8 shows a cell arrangement in accordance with an embodiment of the invention;

FIG. 9 shows a method for manufacturing a cell in accordance with an embodiment of the invention;

FIG. 10 shows a method for manufacturing a cell in accordance with an embodiment of the invention; and

FIGS. 11A and 11B show a memory module (FIG. 11A) and a stackable memory module (FIG. 11B) in accordance with an embodiment of the invention.

### DETAILED DESCRIPTION OF ILLUSTRATIVE EMBODIMENTS

The present invention relates generally to integrated circuits, to a cell, to a cell arrangement, to a method for manufacturing an integrated circuit, to a method for manufacturing a cell, and to a memory module.

In a conventional planar charge trapping memory cell (e.g., in a NAND architecture), with ongoing scaling of its dimensions, a so called equivalent oxide thickness (EOT) of smaller than approximately 10 nm (EOT<10 nm) of the dielectric stack used for charge trapping is desirable in order to control short channel effects.

A conventional semiconductor-oxide-nitride-oxide-semiconductor (SONOS) memory cell usually fails in achieving the EOT of smaller than approximately 10 nm of the dielectric stack in combination with a high threshold voltage (ΔVₜₕ) shift of greater than approximately 4 V and with a reliable retention.

One reason for this may be related to the conventionally provided erase operation yielding slow tunneling currents if a tunnel oxide having a thickness larger than approximately 3.5 nm are used. However, a thinner tunnel oxide may comprise the retention properties of the memory cell.

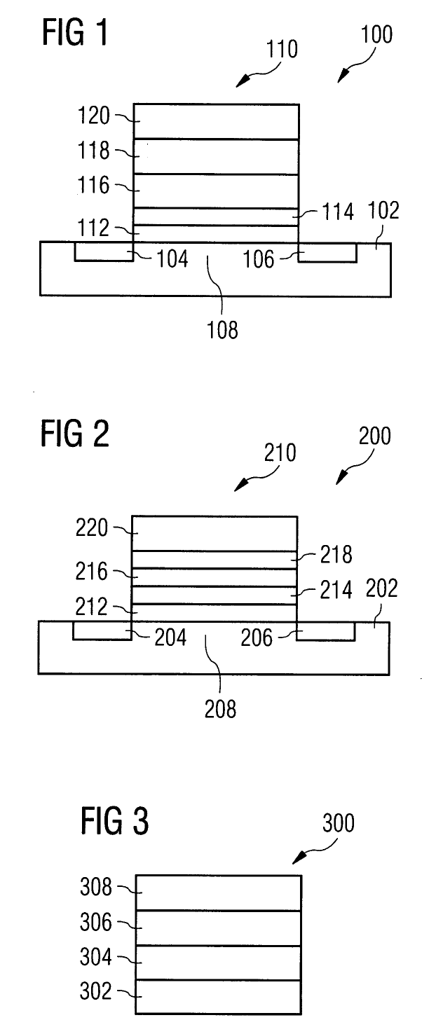

FIG. 1 shows a cross sectional view of a conventional memory cell 100, also referred to as a tantalum-nitride-aluminum oxide-nitride-oxide-silicon (TANOS) memory cell 100.

The memory cell 100 shown in FIG. 1 includes a substrate 102, e.g., a silicon substrate. A first source/drain region 104 and a second source/drain region 106 are provided in the substrate 102.

Furthermore, an active region 108 is provided in the substrate 102 between the first source/drain region 104 and the second source/drain region 106. The active region 108 may be rendered electrically conductive (in other words form a conductive channel) in response to an appropriate voltage application to a gate region and to the first source/drain region 104 and the second source/drain region 106.

Furthermore, the memory cell 100 includes a gate stack 110 arranged on or above the active region 108. The gate stack 110 includes a dielectric composite of three layers, namely a silicon oxide layer 112 (e.g., having a thickness of about 4 nm) arranged on or above the active region 108, a silicon nitride layer 114 (acting as a charge trapping layer and, e.g., having a thickness of about 6.5 nm) arranged on or above the silicon oxide layer 1112, and an aluminum oxide layer 116 (e.g., having a thickness of about 15 nm) arranged on or above the silicon nitride layer 114. The gate stack 110 further includes a tantalum nitride electrode layer 118 (e.g., having a thickness of about 17 nm) arranged on or above the aluminum oxide layer 116 and a tungsten nitride/tungsten electrode 120 (used to reduce the gate resistance) arranged on or above the tantalum nitride electrode layer 118.

The memory cell 100 helps to achieve a rather large threshold voltage (Vₜₕ) shift with good retention properties, since it is able to suppress the gate currents during an erase process erasing the memory cell 100. However, the total equivalent oxide thickness (EOT) of the memory cell 100 is about 12 μm and thus is still above the desired 10 nm and the required oxide fields during erase are very high (usually larger than 15 MV/cm), thus causing reliability issues. The memory cell 100 further shows an endurance below 1 k program/erase cycles. Furthermore, the required programming voltages are rather high, even in the region of the required programming voltages for a floating gate memory cell.

FIG. 2 shows a cross sectional view of another conventional memory cell 200.

The memory cell 200 shown in FIG. 2 includes a substrate 202, e.g., a silicon substrate. A first source/drain region 204 and a second source/drain region 206 are provided in the substrate 202.

Furthermore, an active region 208 is provided in the substrate 202 between the first source/drain region 204 and the second source/drain region 206. The active region 208 may be rendered electrically conductive (in other words form a conductive channel) in response to an appropriate voltage application to a gate region and to the first source/drain region 204 and the second source/drain region 206.

Furthermore, the memory cell 200 includes a gate stack 210 arranged on or above the active region 208. The gate stack 210 includes a silicon oxide layer 212 on or above the active region 208, a trapless silicon nitride layer 214 (since the trapless silicon nitride layer 214 has substantially no traps, it does not act as a charge trapping layer for trapping electrical charge carriers) on or above the silicon oxide layer 212 and a silicon nitride layer 216 (acting as a charge trapping layer) arranged on or above the trapless silicon nitride layer 214. The gate stack 210 further includes a silicon oxide layer 218 arranged on or above the silicon nitride layer 216 and a poly-silicon layer 220 (acting as a gate region) arranged on or above the silicon oxide layer 218.

The gate stack 210 including the trapless silicon nitride layer 214 is useful in principle since it allows to use a layer thickness of the silicon oxide layer 212 of about 2 nm without compromising its retention characteristics. However, the technical realisation of such a gate stack 210 is difficult due to the required annealing processes equalizing the properties of the both silicon nitride layers in the gate stack 210, namely the properties of the trapless silicon nitride layer 214 and the silicon nitride layer 216.

FIG. 3 shows a cross sectional view of a dielectric layer stack 300 of a memory cell in accordance with an embodiment of the invention.

In an embodiment of the invention, the dielectric layer stack 300 is composed of the following four layers:

a low-k dielectric layer 302;

a first high-k dielectric layer 304 arranged on or above the low-k dielectric layer 302 (the first high-k dielectric layer may have a valence band offset that is smaller than 3.5 eV; in an embodiment of the invention, the first high-k dielectric layer has a thickness in the range of approximately 2 nm to 10 nm);

a charge trapping layer 306 arranged on or above the first high-k dielectric layer 304 (in an embodiment of the invention, the material of the charge trapping layer is a material selected from a group of materials consisting of: silicon nitride, aluminum oxide, yttrium oxide, hafnium oxide, lanthanum oxide, zirconium oxide, amorphous silicon, tantalum oxide, titanium oxide, aluminum nitride, an aluminate, nanocrystalline material (e.g., tungsten (W) or silicon (Si)), silicon based nanocrystals, multi-layer stack including silicon nitride (Si₃N₄) and another high-k material (which may increase the number f interfaces);

a second high-k dielectric layer 308 arranged on or above the charge trapping layer 306.

In an embodiment of the invention, the material of the low-k dielectric layer 302 has a dielectric constant of equal to or smaller than 3.9.

In an embodiment of the invention, the material of the low-k dielectric layer 302 is a material selected from a group of materials consisting of: silicon oxide (SiOₓ), silicon oxinitride (SiON), silicates, and silicon nitride (Si₃N₄).

In an embodiment of the invention, the low-k dielectric layer 302, e.g., has a thickness in the range of about 1 nm to about 4 nm, e.g., in the range of about 1.5 nm to about 3.5 nm, e.g., in the range of about 2 nm to about 3 nm.

In an embodiment of the invention, the material of the first high-k dielectric layer 304 has a dielectric constant of greater than 3.9. In another embodiment of the invention, the material of the first high-k dielectric layer 304 has a dielectric constant of equal to or greater than 7, e.g., equal to or greater than 9.5, e.g., equal to or greater than 15, e.g., equal to or greater than 20, e.g., equal to or greater than 22, e.g., equal to or greater than 25, e.g., equal to or greater than 27.

In an embodiment of the invention, the material of the first high-k dielectric layer 304 is a material selected from a group of materials consisting of: hafnium silicon oxynitride (HfSiON), silicon nitride (Si₃N₄), aluminum oxide (Al₂O₃), zirconium oxide (ZrO₂), lanthanum oxide (La₂O₃), hafnium aluminum oxide (HfAlO), aluminates, and other mixtures of high-k materials, in other words, other mixtures of materials having a dielectric constant greater than 3.9.

In an embodiment of the invention, the first high-k dielectric layer 304 is a trapless high-k dielectric layer 304. In one embodiment of the invention, the trapless high-k dielectric layer 304 is to be understood as being a high-k dielectric layer 304 having substantially no traps, e.g., less than 5*10¹⁸ traps/cm³, e.g., less than 1*10¹⁸ traps/cm³.

In an embodiment of the invention, the first high-k dielectric layer 304 has a layer thickness in the range of about 2 nm to about 6 nm, e.g., in the range of about 3 nm to about 5 nm, e.g., in the range of about 3.5 nm to about 4.5 nm, e.g., a layer thickness of about 4 nm. Specifically, in connection with a first low-k layer having or consisting of SiO₂ or SiOₓ or SiON the first high-k layer should be beyond 2 nm in order to fulfill the retention improvement sufficiently.

In an embodiment of the invention, the charge trapping layer 306 may include or consist of one or more materials being selected from a group of materials that consists of: silicon nitride (Si₃N₄), aluminum oxide (Al₂O₃), yttrium oxide (Y₂O₃), hafnium oxide (HfO₂), hafnium aluminum oxide (HfAlO), lanthanum oxide (LaO₂), zirconium oxide (ZrO₂), amorphous silicon (a-Si), tantalum oxide (Ta₂O₅), titanium oxide (TiO₂), and/or an aluminate. An example for an aluminate is an alloy of the components aluminum, zirconium and oxygen (AlZrO). Alternatively, the charge trapping layer may contain nanocrystalline centers of approximately 2 nm to approximately 5 nm in size made of a metallic material or semiconducting material or dielectric material with a conduction band offset smaller than the first high-k layer. For instance, tungsten (W) or silicon (Si) nanocrystals may be used. In this way the number of stored charges may be increased.

In an embodiment of the invention, the charge trapping layer 306 has a layer thickness in the range of about 4 nm to about 8 nm, e.g., in the range of about 5 nm to about 7 nm, e.g., in the range of about 5.5 nm to about 6.5 mm, e.g., a layer thickness of about 6 nm.

In an embodiment of the invention, the material of the first high-k dielectric layer 304 is different from the material selected for the charge trapping layer 306. In this way, it is possible to prevent equalization of the properties of the first high-k dielectric layer 304 and the charge trapping layer 306. Thus, it is possible to ensure that the first high-k dielectric layer 304 illustratively acts as a buffer layer (substantially without traps) for improved retention characteristics and does not act as a charge trapping layer, and that the charge trapping layer 306 is the only layer in the layer stack 300 that actually acts as a charge trapping layer trapping electrical charges.

In an embodiment of the invention, the material of the second high-k dielectric layer 308 has a dielectric constant of greater than 3.9. In another embodiment of the invention, the material of the second high-k dielectric layer 308 has a dielectric constant of equal to or greater than 7.8, e.g., equal to or greater than 9.5, e.g., equal to or greater than 15, e.g., equal to or greater than 20, e.g., equal to or greater than 22, e.g., equal to or greater than 25, e.g., equal to or greater than 27.

In an embodiment of the invention, the material of the second high-k dielectric layer 308 is a material selected from a group of materials consisting of: hafnium silicon oxynitride (HfSiON), silicon nitride (Si₃N₄), aluminum oxide (Al₂O₃), zirconium oxide (ZrO₂), lanthanum oxide (La₂O₃), aluminates, silicon oxinitride (SiON).

In an embodiment of the invention the material of the dielectric which is disposed above the charge trapping layer consists of a double layer of type low-k and high-k, e.g., SiO₂/SiOₓ of a thickness in the range of approximately 0.2 nm to approximately 4 nm and one material of the above mentioned high k materials.

In an embodiment of the invention, the material of the second high-k dielectric layer 308 is the same material as the material of the first high-k dielectric layer 304.

In an embodiment of the invention, the second high-k dielectric layer 308 has a layer thickness in the range of about 4 nm to about 11 nm, e.g., in the range of about 5 nm to about 10 nm, e.g., in the range of about 6 nm to about 9 nm.

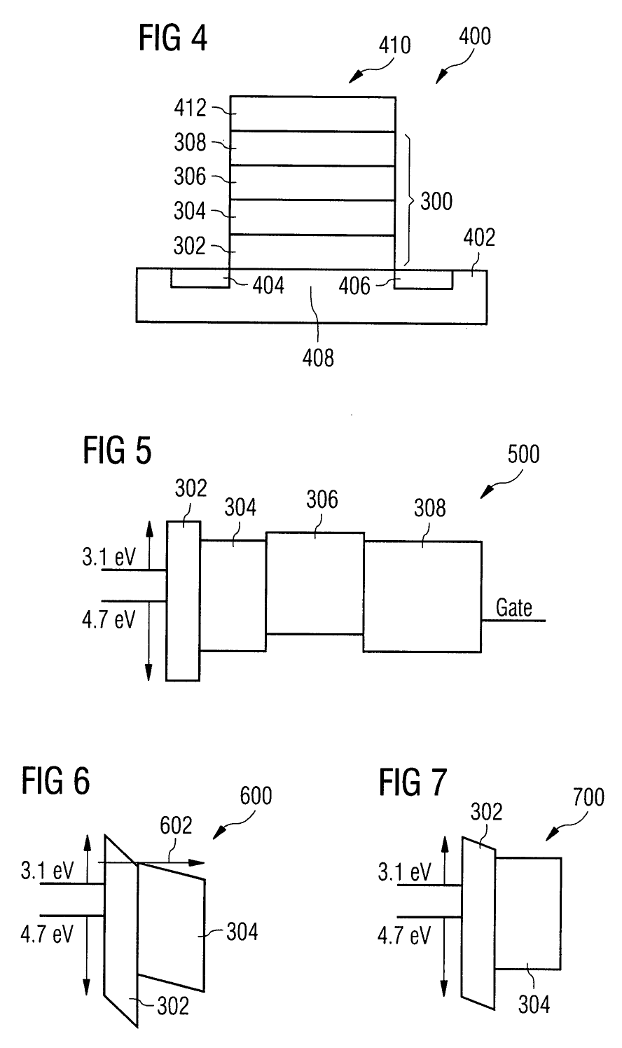

FIG. 4 shows a cross sectional view of a cell 400 in accordance with an embodiment of the invention. In a particular embodiment of the invention, the cell 400 is a memory cell 400.

It should be mentioned that in an embodiment of the invention, the described cells as well as the described cell arrangements may be monolithically integrated in one integrated circuit or in a plurality of integrated circuits.

In an embodiment of the invention, the cell 400 may include a carrier 402, e.g., a substrate 402. In a particular embodiment of the invention, the substrate 402 is made of semiconductor material, although in another embodiment of the invention, other suitable materials can also be used, e.g., polymers. In an exemplary embodiment of the invention, the substrate 402 is made of silicon (doped or undoped). In an alternative embodiment of the invention, the substrate 402 is a silicon on insulator (SOI) wafer. As an alternative, any other suitable semiconductor materials can be used for the substrate 402, for example semiconductor compound materials such as gallium arsenide (GaAs), indium phosphide (InP), but also any suitable ternary semiconductor compound material or quaternary semiconductor compound material such as, e.g., indium gallium arsenide (InGaAs).

In one embodiment of the invention, the cell 400 is a transistor-type cell, e.g., a transistor-type memory cell (e.g., a field effect transistor-type cell). The cell 400 may include a first source/drain region 404 and a second source/drain region 406.

Furthermore, an active region 408 is provided in the substrate 402 between the first source/drain region 404 and the second source/drain region 406. The active region 408 may be rendered electrically conductive (in other words form a conductive channel) in response to an appropriate voltage application to a gate region (which will be described in more detail below) and to the first source/drain region 404 and the second source/drain region 406.

Furthermore, the memory cell 400 includes a gate stack 410 arranged on or above the active region 408. The gate stack 410 may include the dielectric layer stack 300 as shown and described with reference to FIG. 3. The gate stack 410 may further include a gate region 412 made of electrically conductive material such as, e.g., poly-silicon (doped or undoped). In an alternative embodiment of the invention, any other suitable electrically conductive material may be used. The gate region 412 is, e.g., arranged on or above the second high-k dielectric layer 308 of the dielectric layer stack 300. In an embodiment of the invention, the gate region is made of a material selected from a group of materials selected from polysilicon, tungsten (W), tantalum nitride (TaN), titanium nitride (TiN), carbon, aluminum (Al).

Although the described cell 400 is a planar cell, in an alternative embodiment of the invention, the cell may have a different structure. In one embodiment of the invention, the cell may be a fin field effect transistor (FinFET), which may be understood to mean a field effect transistor including a fin, e.g., a ridge structure or a bridge structure, which is formed or freely suspended on a substrate, wherein the active region of the field effect transistor is arranged within the fin. In one embodiment of the invention, the cell may be a multi-gate field effect transistor (MuGFET), which may be understood to mean a fin field effect transistor, in which an active region is driven from at least two sides of the fin. A MuGFET driven from three sides is also referred to as a triple-gate field effect transistor or trigate field effect transistor and may also be provided as the cell. In these embodiments, the dielectric layer stack 300 may descriptively be wrapped around the fin structure and may have an inverted U-shape, for example. Any other desired shape of a cell including, e.g., the dielectric layer stack 300 may be provided in an alternative embodiment of the invention.

In an embodiment of the invention, the cell 400 is a volatile memory cell 400.

In one embodiment of the invention, the memory cell 400 is a non-volatile memory cell, e.g., a non-volatile random access memory cell (NVRAM cell).

In the context of this description, a “volatile memory cell” may be understood as a memory cell storing data, the data being refreshed during a power supply voltage of the memory system being active, in other words, in a state of the memory system, in which it is provided with a power supply voltage. In contrast thereto, a “non-volatile memory cell” may be understood as a memory cell storing data, wherein the stored data is/are not refreshed during the power supply voltage of the memory system being active.

However, a “non-volatile memory cell” in the context of this description includes a memory cell, the stored data of which may be refreshed after an interruption of the external power supply. As an example, the stored data may be refreshed during a boot process of the memory system after the memory system had been switched off or had been transferred to an energy deactivation mode for saving energy, in which mode at least some or most of the memory system components are deactivated. Furthermore, the stored data may be refreshed on a regular timely basis, but not, as with a “volatile memory cell” every few picoseconds or nanoseconds or milliseconds, but rather in a range of hours, days, weeks or months.

FIG. 5 shows an energy band diagram 500 of a memory cell in accordance with an embodiment of the invention without external voltages being applied.

As shown in FIG. 5, in the embodiment of the invention, in which the first high-k dielectric layer 304 and the second high-k dielectric layer 308 are made of the same material or of different materials having a similar energy band characteristic (e.g., in case that the first high-k dielectric layer 304 is made of hafnium silicon oxynitride (HfSiON) and the second high-k dielectric layer 308 is made of hafnium silicon oxynitride (HfSiON) or aluminum oxide (Al₂O₃)), a substantially symmetric band structure is provided around the charge trapping layer 306.

In an embodiment of the invention, a compositionally different trapless high-k buffer layer (e.g., the first high-k dielectric layer 304) compared to the trapping layer (e.g., the charge trapping layer 306) is provided.

In an embodiment of the invention, a fast injection of holes and electrons at moderate electrical fields in the range of about 11 MV/cm to about 13 MV/cm as well as an EOT in the range of about 8 nm to about 10 nm and required programming voltages and erase voltages of less than approximately 14 V are achieved.

FIG. 6 shows an energy band diagram 600 of a portion of a memory cell in accordance with an embodiment of the invention in a programming mode.

In this case, electrical potentials are applied to the gate region 412, the first source/drain region 404 and the second source/drain region 406 such that electrons can tunnel through the very thin low-k dielectric layer 302 (e.g., having a thickness of only about 2 μm) via the trapless high-k buffer layer (e.g., the first high-k dielectric layer 304), the fermi level of which is substantially reduced, into the charge trapping layer 306 (not shown in FIG. 6). The injection of electrons from the carrier 402 through the low-k dielectric layer 302 and the first high-k dielectric layer 304 into the charge trapping layer 306 is symbolized in FIG. 6 by means of an arrow 602. Illustratively, in this case, the first high-k dielectric layer 304 does not represent a remarkable barrier for the electrons during the programming of the cell (e.g., the cell 400).

In one embodiment of the invention, the following electrical potentials are applied to the respective regions for programming (it is to be noted that in an embodiment of the invention, the memory cells are connected with each other in a NAND structure, wherein the 0 V voltage is supplied via the respective bit line, not directly via a metal line which is directly connected to the first source/drain region and the second source/drain region, respectively):
first source/drain region 404 (in an embodiment of the invention, the substrate): about 0 V to about 3 V;
second source/drain region 406: about 0 V to about 3 V;
gate region 412: about 8 V to about 16 V;

In one embodiment of the invention, the following electrical potentials are applied to the respective regions for erasing (it is to be noted that in an embodiment of the invention, the memory cells are connected with each other in a NAND structure, wherein the erasure is carried out using only the substrate, the first source/drain region and the second source/drain region are not contacted in this case, they are floating, the bit line is also floating):
first source/drain region 404 (in an embodiment of the invention, the substrate): about 10 V to about 18 V;
second source/drain region 406: about 10 V to about 18 V;
gate region 412: about −3 V to about 3 V;

In one embodiment of the invention, the following electrical potentials are applied to the respective regions for reading (it is to be noted that in an embodiment of the invention, the memory cells are connected with each other in a NAND structure, wherein all memory cells in a memory cell string of, e.g., 32 memory cells receive a word line voltage in the range of about 4 V to about 7 V so that they are opened; about 1 V is supplied to the bit line; about 0 V is supplied to the source line):
first source/drain region 404: about 0 V to about 2 V;
second source/drain region 406: about 0 V to about 2 V;
gate region 412: about 0 V to about 3 V;

FIG. 7 shows an energy band diagram 700 of a portion of a memory cell in accordance with an embodiment of the invention in a non-programming mode, for example in a reading mode.

As shown in FIG. 7, only a slight bending of the energy band structure of the low-k dielectric layer 302 occurs, since the voltages for reading content from a memory cell are lower. Furthermore, a smaller field drops across the energy band structure of the first high-k dielectric layer 304 compared to the low-k layer. Thus, a very high energy barrier is formed by the energy band structure of the first high-k dielectric layer 304 even during a read operation, thereby achieving good retention properties in a memory cell in accordance with an embodiment of the invention.

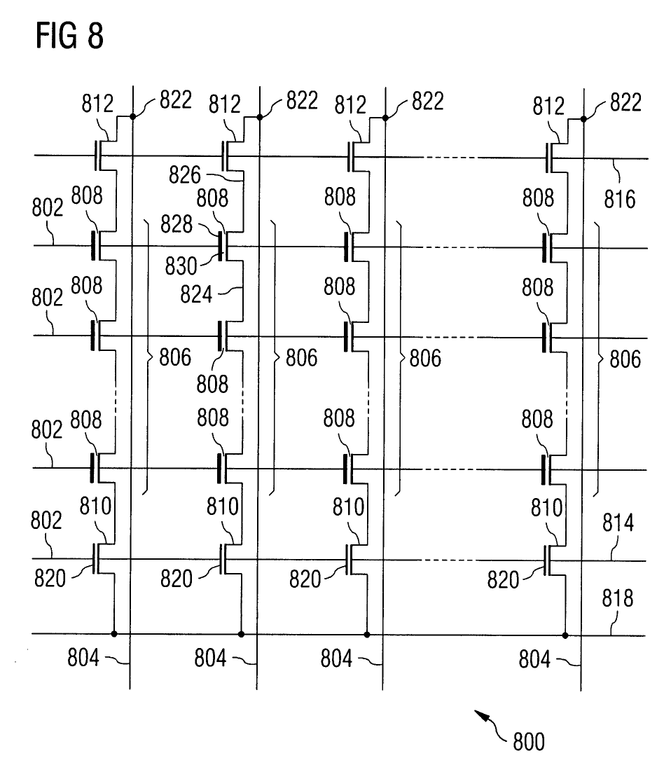

FIG. 8 shows a cell arrangement 800 in accordance with an embodiment of the invention.

In one embodiment of the invention, the cell arrangement 800 is a NAND memory cell array 800 as a part of the memory device (in general, as a part of an electronic device including the cell arrangement 800). The NAND memory cell array 800 includes word lines 802 (in general, an arbitrary number of word lines 802, in one embodiment of the invention, 1024 word lines 802) and intersecting bit lines 804 (in general, an arbitrary number of bit lines 804, in one embodiment of the invention, 512 bit lines 204).

The NAND memory cell array 800 includes NAND strings 806, each NAND string 806 having charge trapping memory cells 808 (e.g., charge trapping transistor-type memory cells 400 as shown in FIG. 4). Furthermore, an arbitrary number of charge trapping memory cells 808 can be provided in the NAND string 806, in accordance with one embodiment of the invention, 32 or 64 charge trapping memory cells 808. The charge trapping memory cells 808 are connected in series source-to-drain between a source select gate 810, which may be implemented as a field effect transistor, and a drain select gate 812, which may also be implemented as a field effect transistor. Each source select gate 810 is positioned at an intersection of a bit line 804 and a source select line 814. Each drain select gate 812 is positioned at an intersection of a bit line 804 and a drain select line 816. The drain of each source select gate 810 is connected to the source terminal of the first charge trapping memory cells 808 of the corresponding NAND string 806. The source of each source select gate 810 is connected to a common source line 818. A control gate 820 of each source select gate 810 is connected to the source select line 814.

In one embodiment of the invention, the common source line 818 is connected between source select gates 810 for NAND strings 806 of two different NAND arrays. Thus, the two NAND arrays share the common source line 818.

In an embodiment of the invention, the drain of each drain select gate 812 is connected to the bit line 804 of the corresponding NAND string 806 at a drain contact 822. The source of each drain select gate 812 is connected to the drain of the last charge trapping memory cell 808 of the corresponding NAND string 806. In one embodiment of the invention, at least two NAND strings 806 share the same drain contact 822.

In accordance with the described embodiments, each charge trapping memory cell 808 includes a source 824 (e.g., the first source/drain region 404), a drain 826 (e.g., the second source/drain region 406), a charge storage region 828 (e.g., the dielectric layer stack 300) and a control gate 830 (e.g., the gate region 412). The control gate 830 of each charge trapping memory cell 808 is connected to a respective word line 802. A column of the NAND memory cell array 800 includes a respective NAND string 806 and a row of the NAND memory cell array 800 includes those charge trapping memory cells 808 that are commonly connected to a respective word line 802.

In an alternative embodiment of the invention, the cell arrangement 800 is a NOR memory cell array 800. In yet another embodiment of the invention, the cell arrangement 800 may be arranged in accordance with any other suitable architecture.

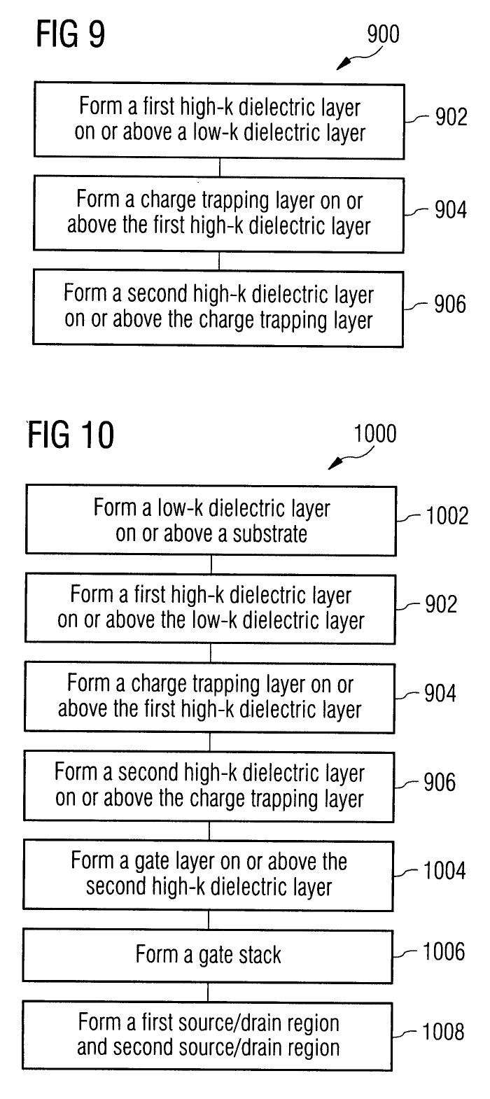

FIG. 9 shows a method 900 for manufacturing a cell in accordance with an embodiment of the invention.

At 902, a first high-k dielectric layer is formed on or above a low-k dielectric layer. In an embodiment of the invention, the first high-k dielectric layer (e.g., 304) may be deposited on the low-k dielectric layer (e.g., 302) by means of a deposition process, e.g., by means of a chemical vapour deposition (CVD) process or by means of a physical vapour deposition (PVD) process.

In an embodiment of the invention, silicon oxide may be used as the material of the low-k dielectric layer (e.g., 302) and hafnium silicon oxynitride (or any other material described above) may be used as the material for the first high-k dielectric layer (e.g., 304). In an embodiment of the invention, the low-k dielectric layer (e.g., 302) e.g., has a thickness in the range of about 1 nm to about 4 nm, e.g., in the range of about 1.5 nm to about 3.5 nm, e.g., in the range of about 2 nm to about 3 nm. The first high-k dielectric layer (e.g., 304) may be deposited with a layer thickness in the range of about 2 nm to about 6 nm, e.g., in the range of about 3 nm to about 5 nm, e.g., in the range of about 3.5 nm to about 4.5 nm, e.g., a layer thickness of about 4 nm.

In an embodiment of the invention, the deposition of the first high-k dielectric layer (e.g., 304) is carried out such that substantially no traps are formed in the deposited material. This can be achieved in that the deposition process is carried out using the following parameters, for example for nitrided hafnium silicon oxide (HfSiO):

Co-sputtering of Hf/Si in Ar/O₂/N₂ atmosphere.

Nitridation: 10 to 30 at. % for instance by varying N₂/O₂ ratio or by NH₃ anneal.

In an embodiment of the invention, the first high-k layer is amorphous even after the source drain anneals. This is controlled by the degree of nitridation of the hafnium silicon oxide (HfSiO).

In an embodiment of the invention, the nitridation is such that the valence band offset is reduced by at least 1 eV.

In an embodiment of the invention, the first high-k layer is crystalline or polycrystalline.

At 904, a charge trapping layer is formed on or above the first high-k dielectric layer. In an embodiment of the invention, the charge trapping layer (e.g., 306) may be deposited on the first high-k dielectric layer (e.g., 304) by means of a deposition process, e.g., by means of a chemical vapour deposition (CVD) process or by means of a physical vapour deposition (PVD) process.

In an embodiment of the invention, a nitride, e.g., silicon nitride or aluminum nitride, or any other suitable material (e.g., one of the materials described above) may be used as a material for the charge trapping layer (e.g., 306).

The charge trapping layer (e.g., 306) may be deposited with a layer thickness in the range of about 4 nm to about 8 nm, e.g., in the range of about 5 nm to about 7 nm, e.g., in the range of about 5.5 nm to about 6.5 nm, e.g., a layer thickness of about 6 nm.

At 906, a second high-k dielectric layer is formed on or above the charge trapping layer. In an embodiment of the invention, the second high-k dielectric layer (e.g., 308) may be deposited on the charge trapping layer (e.g., 306) by means of a deposition process, e.g., by means of a chemical vapour deposition (CVD) process or by means of a physical vapour deposition (PVD) process.

In an embodiment of the invention, hafnium silicon oxynitride (or any other material described above) may be used as the material for the second high-k dielectric layer (e.g., 308). The second high-k dielectric layer (e.g., 308) may be deposited with a layer thickness in the range of about 4 nm to about 11 nm, e.g., in the range of about 5 nm to about 10 nm, e.g., in the range of about 6 nm to about 9 nm.

FIG. 10 shows a method 1000 for manufacturing a cell in accordance with an embodiment of the invention.

At 1002, a low-k dielectric layer is formed on or above a substrate, e.g., a silicon substrate. In an embodiment of the invention, the low-k dielectric layer (e.g., 302) may be deposited on the substrate (e.g., 402) by means of a deposition process, e.g., by means of a chemical vapour deposition (CVD) process or by means of a physical vapour deposition (PVD) process. In an alternative embodiment of the invention, the low-k dielectric layer (e.g., 302) may be manufactured by partially oxidizing the substrate (e.g., 402).

In an embodiment of the invention, silicon oxide may be used as the material of the low-k dielectric layer (e.g., 302) (or any other material described above). In an embodiment of the invention, the low-k dielectric layer (e.g., 302) may be deposited with a layer thickness in the range of about 0.2 nm to about 4 nm, e.g., in the range of about 1.5 nm to about 3.5 nm, e.g., in the range of about 2 nm to about 3 nm.

Then, the method 900 is carried out. This means, as described above, at 902, a first high-k dielectric layer is formed on or above the low-k dielectric layer. Furthermore, at 904, a charge trapping layer is formed on or above the first high-k dielectric layer. Further, at 906, a second high-k dielectric layer is formed on or above the charge trapping layer.

Then, in FIG. 10, at 1004, a gate layer is formed on or above the second high-k dielectric layer. In an embodiment of the invention, poly-silicon (or any other suitable electrical conductive material) may be used as the material for the gate layer.

At 1006, a gate stack (e.g., 410) is formed, e.g., by photolithographic patterning (e.g., using an etch process, e.g., a wet etch process or a dry etch process) the layer stack composed of the low-k dielectric layer, the first high-k dielectric layer, the charge trapping layer, and the second high-k dielectric layer and the gate. By doing this, some regions of the upper surface of the substrate 402 are exposed.

Then, in an embodiment of the invention, at 1008, a first source/drain region (e.g., 404) and a second source/drain region (e.g., 406) are formed, e.g., by implanting doping atoms (in an embodiment of the invention using spacers (e.g., made of an oxide or a nitride) to protect the sidewalls of the gate stack (e.g., 410) during implantation into those exposed areas of the substrate (e.g., 402), in which the first source/drain region (e.g., 404) and the second source/drain region (e.g., 406) should be formed.

Then, the conventional processes for completing the memory cell arrangement are executed, e.g., Back-End-Of-Line processes (BEOL) such as for example wiring, packaging, etc.

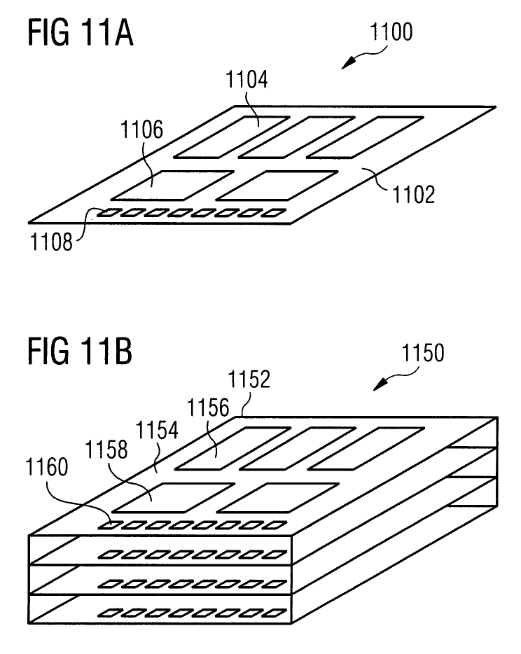

As shown in FIGS. 11A and 11B, in some embodiments, memory devices such as those described herein may be used in modules. In FIG. 11A, a memory module 1100 is shown, on which one or more memory devices 1104 are arranged on a substrate 1102. The memory device 1104 may include numerous memory cells, each of which uses a memory element in accordance with an embodiment of the invention. The memory module 1100 may also include one or more electronic devices 1106, which may include memory, processing circuitry, control circuitry, addressing circuitry, bus interconnection circuitry, or other circuitry or electronic devices that may be combined on a module with a memory device, such as the memory device 1104. Additionally, the memory module 1100 includes multiple electrical connections 1108, which may be used to connect the memory module 1100 to other electronic components, including other modules.

As shown in FIG. 11B, in some embodiments, these modules may be stackable, to form a stack 1150. For example, a stackable memory module 1152 may contain one or more memory devices 1156, arranged on a stackable substrate 1154. The memory device 1156 contains memory cells that employ memory elements in accordance with an embodiment of the invention. The stackable memory module 1152 may also include one or more electronic devices 1158, which may include memory, processing circuitry, control circuitry, addressing circuitry, bus interconnection circuitry, or other circuitry or electronic devices that may be combined on a module with a memory device, such as the memory device 1156. Electrical connections 1160 are used to connect the stackable memory module 1152 with other modules in the stack 1150, or with other electronic devices. Other modules in the stack 1150 may include additional stackable memory modules, similar to the stackable memory module 1152 described above, or other types of stackable modules, such as stackable processing modules, control modules, communication modules, or other modules containing electronic components.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An integrated circuit having a cell, the cell comprising:
a low-k dielectric layer;
a first high-k dielectric layer disposed above the low-k dielectric layer;
a charge trapping layer disposed above the first high-k dielectric layer; and
a second high-k dielectric layer disposed above the charge trapping layer.

2. The integrated circuit of claim 1, wherein the low-k dielectric layer comprises a material having a dielectric constant of equal to or smaller than 3.9.

3. The integrated circuit of claim 1, wherein the low-k dielectric layer comprises a material selected from the group of materials consisting of silicon oxide, silicon oxinitride, silicates, SiOₓ, and high-k material having silicon oxide.

4. The integrated circuit of claim 1, wherein the first high-k dielectric layer comprises a material having a dielectric constant of greater than 3.9.

5. The integrated circuit of claim 4, wherein the first high-k dielectric layer comprises a material having a dielectric constant of equal to or greater than 7.

6. The integrated circuit of claim 1, wherein the first high-k dielectric layer comprises a material selected from the group of materials consisting of nitrided hafnium silicate, silicon nitride, aluminum oxide, zirconium oxide, lanthanum oxide, hafnium aluminum oxide, and mixtures of high-k materials, aluminate.

7. The integrated circuit of claim 1, wherein the first high-k dielectric layer comprises a trapless high-k dielectric layer.

8. The integrated circuit of claim 1, wherein the first high-k dielectric layer has a valence band offset that is smaller than 3.5 eV.

9. The integrated circuit of claim 1, wherein the first high-k dielectric layer has a thickness in the range of approximately 2 nm to approximately 10 nm.

10. The integrated circuit of claim 1, wherein the charge trapping layer comprises a material selected from the group consisting of silicon nitride, aluminum oxide, yttrium oxide, hafnium oxide, lanthanum oxide, zirconium oxide, amorphous silicon, tantalum oxide, titanium oxide, aluminum nitride, an aluminate, nanocrystalline material, silicon based nanocrystals, multi-layer stack including silicon nitride and another high-k material.

11. The integrated circuit of claim 1, wherein the second high-k dielectric layer has a dielectric constant of greater than 3.9.

12. The integrated circuit of claim 9, wherein the second high-k dielectric layer has a dielectric constant of equal to or greater than 7.

13. The integrated circuit of claim 1, wherein the second high-k dielectric layer comprises a material selected from the group of materials consisting of hafnium silicon oxynitride, silicon nitride, aluminum oxide, zirconium oxide, lanthanum oxide, an aluminate, and silicon oxinitride.

14. The integrated circuit of claim 1, wherein the cell comprises a memory cell.

15. The integrated circuit of claim 1, wherein the first high-k dielectric layer and the second high-k dielectric layer comprise the same material.

16. The integrated circuit of claim 1, the cell further comprising a gate region disposed above the second high-k dielectric layer.

17. The integrated circuit of claim 16, wherein the gate region comprises at least one material selected from the group consisting of polysilicon, tungsten, tantalum nitride, titanium nitride, carbon, aluminum.

18. A cell, comprising:
a low-k dielectric layer;
a first high-k dielectric layer disposed above the low-k dielectric layer;
a charge trapping layer disposed above the first high-k dielectric layer; and
a second high-k dielectric layer disposed above the charge trapping layer.

19. The cell of claim 18, wherein the low-k dielectric layer comprises a material selected from the group consisting of silicon oxide, silicon oxinitride, silicate, and silicon nitride.

20. The cell of claim 18, wherein the first high-k dielectric layer comprises a material selected from the group consisting of hafnium silicon oxynitride, silicon nitride, aluminum oxide, zirconium oxide, lanthanum oxide, hafnium aluminum oxide, an aluminate, and a mixture of high-k materials.

21. The cell of claim 18, wherein the first high-k dielectric layer comprises a trapless high-k dielectric layer.

22. The cell of claim 18, wherein the charge trapping layer comprises a material selected from the group of materials consisting of silicon nitride, aluminum oxide, yttrium oxide, hafnium oxide, lanthanum oxide, zirconium oxide, amorphous silicon, tantalum oxide, titanium oxide, aluminum nitride, an aluminate, nanocrystalline material, silicon based nanocrystals, a multi-layer stack including silicon nitride and another high-k material.

23. The cell of claim 18, wherein the second high-k dielectric layer comprises a material selected from the group consisting of hafnium silicon oxynitride, silicon nitride, aluminum oxide, zirconium oxide, lanthanum oxide, an aluminate, and silicon oxinitride.

24. The cell of claim 18, wherein the cell comprises a memory cell.

25. A cell arrangement, comprising:
a plurality of cells, each cell comprising:
a low-k dielectric layer;
a first high-k dielectric layer disposed above the low-k dielectric layer;
a charge trapping layer disposed above the first high-k dielectric layer; and
a second high-k dielectric layer disposed above the charge trapping layer.

26. The cell arrangement of claim 25, wherein the cells are coupled with each other in accordance with a NAND cell arrangement architecture.

27. The cell arrangement of claim 25, wherein the cells are coupled with each other in accordance with a NOR cell arrangement architecture.

28. A method for manufacturing an integrated circuit having a cell, the method comprising:
forming a first high-k dielectric layer on or above a low-k dielectric layer;
forming a charge trapping layer on or above the first high-k dielectric layer; and
forming a second high-k dielectric layer on or above the charge trapping layer.

29. The method of claim 28, wherein the low-k dielectric layer comprises a material selected from the group consisting of silicon oxide, silicon oxinitride, silicate, and silicon nitride.

30. The method of claim 28, wherein the first high-k dielectric layer comprises a material selected from the group consisting of hafnium silicon oxynitride, silicon nitride, aluminum oxide, zirconium oxide, lanthanum oxide, hafnium aluminum oxide, an aluminate, and a mixture of high-k materials.

31. The method of claim 28, wherein the charge trapping layer comprises a material selected from the group consisting of silicon nitride, aluminum oxide, yttrium oxide, hafnium oxide, lanthanum oxide, zirconium oxide, amorphous silicon, tantalum oxide, titanium oxide, aluminum nitride, an aluminate, nanocrystalline material, silicon based nanocrystals, and a multi-layer stack including silicon nitride and another high-k material.

32. The method of claim 28, wherein the second high-k dielectric layer comprises a material selected from the group consisting of hafnium silicon oxynitride, silicon nitride, aluminum oxide, zirconium oxide, lanthanum oxide, an aluminate, and silicon oxinitride.

33. The method of claim 28, further comprising forming a gate region on or above the second high-k dielectric layer.

34. A method for manufacturing a cell, the method comprising:
forming a first high-k dielectric layer on or above a low-k dielectric layer;
forming a charge trapping layer on or above the first high-k dielectric layer; and
forming a second high-k dielectric layer on or above the charge trapping layer.

35. An integrated circuit having a cell, the cell comprising:
a low-k dielectric means;
a first high-k dielectric means disposed above the low-k dielectric means;
a charge trapping means disposed above the first high-k dielectric means; and
a second high-k dielectric means disposed above the charge trapping means.

36. A memory module, comprising:
a plurality of integrated circuits, wherein at least one integrated circuit of the multiplicity of integrated circuits comprises a cell, the cell comprising:
a low-k dielectric layer;
a first high-k dielectric layer disposed above the low-k dielectric layer;
a charge trapping layer disposed above the first high-k dielectric layer; and
a second high-k dielectric layer disposed above the charge trapping layer.

37. The memory module of claim 36, wherein the memory module comprises a stackable memory module in which at least some of the plurality of integrated circuits are stacked one above the other.
